(19) United States
(12) Patent Application Publication
(10) Pub. No.: US 2016/0018636 A1
(43) Pub. Date: Jan. 21, 2016

(54) DISPLAY DEVICE AND MANUFACTURING METHOD OF SAME

(71) Applicant: PIXTRONIX, INC., San Diego, CA (US)

(72) Inventors: Hiroshi Kawanakago, Mobara City (JP); Naohisa Andou, Mobara City (JP)

(73) Assignee: PIXTRONIX INC., San Diego, CA (US)

(21) Appl. No.: 14/774,060

(22) PCT Filed: Mar. 14, 2014
(86) PCT No.: PCT/US2014/028718

§ 371 Date: Sep. 9, 2015

(30) Foreign Application Priority Data
Mar. 14, 2013 (JP) 2013-051974

(51) Int. Cl. G02B 26/02; B81C 1/00; B81B 3/00

(52) U.S. Cl. CPC G02B 26/02; B81B 3/0016; B81C 1/00198; B81C 1/00531

(57) ABSTRACT

[Problem] An object of the present invention is to electrically connect a substrate and an opposing substrate. [Resolving Means] A display device includes a first substrate 10 stacked with a circuit layer 48 for displaying an image, the circuit layer 48 covered by an insulating film 38, the circuit layer 48 including a first conductive film 54, formed with a penetration hole 56 in the insulating film 38, and formed with a hole in a first conductive film 54; a second substrate formed with a second conductive film 40, disposed so that insulating film 38 and the second conductive film 40 are opposed; and a conductive material 60 interposed between the first substrate 10 and the second substrate 12, so that the conductive material touches an inner face of the hole 58 in the first conductive film 54 and the second conductive film 40.

### RELATED APPLICATIONS

The present application for Patent claims priority to Japanese Application No. 2013-051974, entitled “Method of Forming Via Hole Using Laser Irradiation,” filed Mar. 14, 2013, and assigned to the assignee hereof and hereby expressly incorporated by reference herein.

### TECHNICAL FIELD

The present invention relates to display devices and manufacturing method of the same.

### BACKGROUND ART

A MEMS display (micro-electro-mechanical system display) is a display that is expected to replace liquid-crystal displays. (See patent document 1.) This display opens and closes a light-transmissive window using a mechanical shutter method, which differs from the liquid-crystal shutter method which uses polarized light. Specifically, a shutter is equipped for each pixel on a TFT substrate on which a TFT (Thin Film Transistor) is formed. Images are displayed by opening and closing an aperture by moving the shutter in a horizontal direction through electrostatic force.

### PRIOR ART DOCUMENTS

### Patent Documents

[Patent Document 1] Japanese unexamined patent application publication 2008-197668

[Patent Document 2] Japanese unexamined patent application publication 2006-301115

[Patent Document 3] Japanese unexamined patent application publication 2012-108409

### SUMMARY OF THE INVENTION

### Problem to be Solved by the Invention

It is necessary to prevent sticking of the shutter on an opposing substrate in order to open and close the shutter smoothly. For that purpose, electrical continuity of the opposing substrate and TFT substrate was attempted using a conductive material. Such continuity is also required in liquid-crystal display devices as disclosed in patent documents 2 and 3. However, in a case where a surface of the TFT substrate is covered by a passivation layer, it is difficult to implement electrical continuity using conductive materials.

An object of the present invention is to electrically connect a substrate and an opposing substrate.

### Means for Solving the Problem

(1) A manufacturing method of a display device pursuant to the present invention includes preparing a first substrate stacked with a circuit layer for displaying an image, the circuit layer covered by an insulating film, the circuit layer including a first conductive film; forming a hole in the first conductive film by forming a penetration hole in the insulating film using a laser light; preparing a second substrate formed with a second conductive film; and disposing the first substrate and the second substrate by opposing the insulating film and the second conductive film, and interposing a conductive material to touch an inner face of the hole in the first conductive film and the second conductive film. Pursuant to the present invention, the conductive material is securely, electrically connected because it touches an inner face of the hole in the first conductive film penetrating the insulating film that covers the first conductive film. With this, it is possible to electrically connect the first conductive film formed on the first substrate and the second conductive film formed on the second substrate.
(2) In the manufacturing method for the display device described in (1) above, it is acceptable for the hole to be a penetration hole that penetrates the first conductive film.
(3) In the manufacturing method for the display device described in (1) above, it is acceptable for the hole to be a concave portion that does not penetrate the first conductive film, and for the conductive material to be disposed to touch a bottom face of the concave portion.
(4) In the manufacturing method for the display device described in (1) above, it is acceptable for the first conductive film to be composed of a plurality of layers.
(5) A display device pursuant to the present invention includes a first substrate stacked with a circuit layer for displaying an image, the circuit layer covered by an insulating film, the circuit layer including a first conductive film; a hole formed in the first conductive film by forming a penetration hole in the insulating film using a laser light; a second substrate formed with a second conductive film, the first substrate and the second substrate arranged such that the insulating film and the second conductive film oppose each other, and a conductive material interposed between the first substrate and the second substrate so that the conductive material touches an inner face of the hole in the first conductive film and the second conductive film. Pursuant to the present invention, the conductive material is securely, electrically connected because it touches an inner face of the hole in the first conductive film penetrating the insulating film that covers the first conductive film. With this, it is possible to electrically connect the first conductive film formed on the first substrate and the second conductive film formed on the second substrate.
(6) The display device disclosed in (5) may be characterized in that a shutter for controlling the passing and blocking of light, and a drive unit for driving the shutter are disposed on the first substrate, wherein the shutter is covered by an insulating film composed of the same material as the insulating film.
(7) In the display device described in (6) above, it is acceptable for the first conductive layer to be electrically connected to the shutter.

### BRIEF DESCRIPTION OF THE DRAWINGS

FIG. 1 is a sectional view of a display device pursuant to an embodiment of the present invention;

FIG. 2 is a perspective view of a shutter and a drive unit therefor;

FIG. 3 is an explanatory view of a structure for electrically connecting a first substrate and a second substrate;

FIG. 4 is a view to explain the manufacturing method of the display device pursuant to the embodiment of the present invention; and

FIG. 5 is a view to explain a display device pursuant to an alternative embodiment of the present invention.

### MODE FOR CARRYING OUT THE INVENTION

Embodiments of the present invention will now be described below with reference to the drawings.

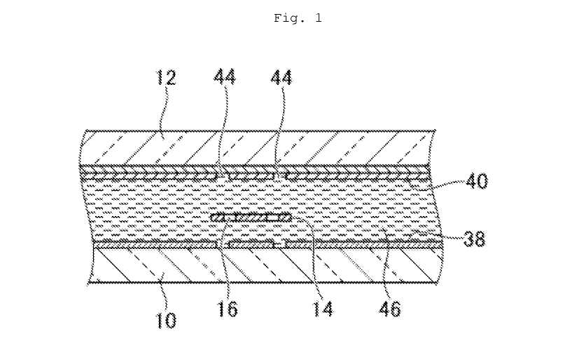

FIG. 1 is a sectional view of a display device pursuant to an embodiment of the present invention. The display device has a first substrate 10, and a second substrate 12, both composed of a light-transmissive material such as glass or the like. The first substrate 10 and the second substrate 12 are opposingly disposed at a distance. A shutter 14 is disposed on the first substrate 10 to control the transmission and blocking of light.

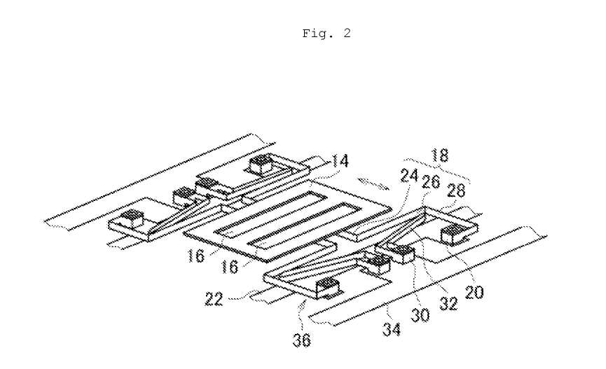

FIG. 2 is a perspective view of the shutter 14 and the drive unit therefor. The shutter 14 is composed of an inorganic material such as a semiconductor or a metal or a similar material; it is a plate that includes drive openings 16. Light passes through the drive openings 16; portions other than the drive openings 16 block light. The drive openings 16 have a long shape in one direction. Furthermore, light is supplied from a backlight, not shown in the drawing, overlapping the first substrate 10.

The shutter 14 is disposed to be suspended from the first substrate 10 supported on a first spring 18. The shutter 14 is supported by a plurality of first springs 18 (four in FIG. 2). The first spring 18 is fastened to the first substrate 10 by a first anchor 20. Specifically, the first anchor 20 is disposed on a first wiring 22 formed on the first substrate 10; both are electrically connected.

The first spring 18 is composed of a material that elastically deforms, and is disposed to deform in a direction parallel to a plate surface of the shutter 14. Specifically, the first spring 18 includes a first unit 24 that extends in a direction away (a direction that intersects (for example, orthogonally) a length direction of the drive opening 16) from the shutter 14; a second unit 26 that extends toward an outside direction from a center of the length direction of the drive opening 16, that is a direction along the length direction of the drive opening 16; and a third unit 28 that extends in a direction further away (a direction that intersects (for example, orthogonally) the length direction of the drive opening 16) from the shutter 14. Also, the shutter 14 is supported on the first spring 18 to be able to move in the direction that intersects the length direction of the drive opening 16 (for example, orthogonally), as indicated by arrows in FIG. 2.

A second spring 32 supported on a second anchor 30 is disposed on the first substrate 10. The second anchor 30 is disposed on a second wiring 34 formed on the first substrate 10, and both are electrically connected. The second spring 32 opposes the second unit 26 of the first spring 18 at a side further away from the shutters 14 than the first unit 24 of the first spring 18. The second unit 26 is pulled toward the second anchor 30 by electrostatic attraction generated by a potential difference across the second spring 32 and the second unit 26 of the first spring 18, by applying a voltage to the second anchor 30. When the second unit 26 is pulled, the shutter 14 is also pulled via the first unit 24 that is connected to the second unit 26. In other words, the first spring 18 and the second spring 32 constitute a drive unit 36 for mechanically driving the shutter 14.

As shown in FIG. 1, an insulating film 38, composed of SiN or a similar material, is formed on the first substrate 10. A second conductive film 40 is formed on the second substrate 12. The second substrate 12 is disposed so that the second conductive film 40 opposes the insulating film 38. If the second conductive film 40 is formed by stacking an aluminum layer and an ITO (Indium Tin Oxide) layer, for example, it will also become a reflective film and a light-blocking film. Light advancing from the first substrate 10 is reflected back, blocking light from passing through. A fixed opening 44 is formed to penetrate, in the second conductive film 40 that acts as a light-blocking film.

The drive opening 16 in the shutter 14 and the fixed opening 44 are arranged at opposing positions. Light passes through if both are aligned. Light is blocked when shielded by the fixed opening 44 by the movement of the shutter 14. Said another way, the shutter 14 is mechanically driven to control the transmission and blocking of light to the fixed opening 44. One shutter 14 corresponds to one pixel; images are displayed by a plurality of pixels. For that reason, a plurality (numerous) of shutters 14 is provided. The shutter 14 and drive unit 36 are arranged in a display region that displays images by a presence of light that passes through the drive opening 16 and the fixed opening 44.

As shown in FIG. 1, the first substrate 10 and the second substrate 12 are fastened at a distance by a sealing material, not shown in the drawing. Oil 46 (for example, silicone oil) fills in the space between the first substrate 10 and the second substrate 12. The shutters 14 and the drive unit 36 are disposed in the oil 46. Because the oil 46 has a low dielectric constant, the drive voltage of the shutters 14 can be lowered. In a case where the first substrate 10 and the second substrate 12 are composed of glass, if the oil 46 has a refractive index that is close to that of glass, by filling with the oil 46, light reflection is reduced at the interface of the first substrate 10 and the second substrate 12.

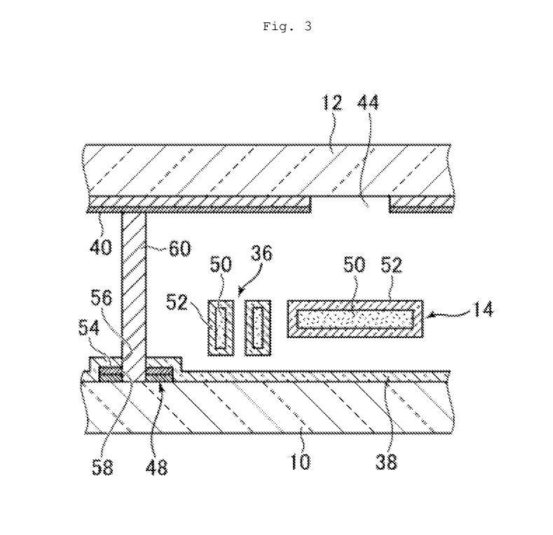

FIG. 3 is a view to explain a structure for electrically connecting a first substrate and a second substrate. A circuit layer 48 for displaying images is laminated to the first substrate 10. The circuit layer 48 is a laminated structure including a thin-film transistor, an electrode, wiring or the like, not shown in the drawing. The circuit layer 48 is covered by the insulating film 38.

The shutter 14 includes a core layer 50 composed of a semiconductor, such as an amorphous silicon. The core layer 50 is covered by an insulating film 52 that is composed of the same material as the insulating film 38. The drive unit 36 for the shutter 14 includes the core layer 50, in the same way. The core layer 50 is covered by the insulating film 52 that is composed of the same material as the insulating film 38.

The circuit layer 48 includes a first conductive film 54. The first conductive film 54 is composed of a plurality of layers (an aluminum layer and an ITO (Indium Tin Oxide) layer). A penetration hole 56 is formed in the insulating film 38. A hole 58 is formed in the first conductive film 54. The hole 58 penetrates the first conductive film 54. The first conductive film 54 is electrically connected to the shutter 14 via the first wiring 22 shown in FIG. 2, for example.

Conductive material 60 interposes the first substrate 10 and the second substrate 12. It is acceptable to use a platinum compound or conductive paste to form the conductive material 60. The conductive material 60 touches an inner face of the hole 58 in the first conductive film 54. The conductive material 60 touches the second conductive film 40. Pursuant to the embodiment, the conductive material 60 is securely, electrically connected by penetrating the insulating film 38 that covers the first conductive film 54 because it touches an inner face of the hole 58 in the first conductive film 54. With this, it is possible to electrically connect the first conductive film 54 formed on the first substrate 10 and the second conductive film 40 formed on the second substrate 12.

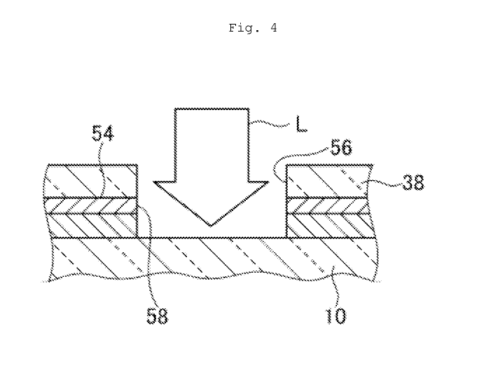

FIG. 4 is a view to explain a manufacturing method of the display device pursuant to one embodiment of the present invention. Pursuant to the embodiment, the first substrate 10 formed with the first conductive film 54 and second substrate 12 formed with the second conductive film 40 (see FIG. 3) are prepared. As shown in FIG. 4, a laser light L can be used to form the penetration hole 56 in the insulating film 38. At this time, the hole 58 is formed in the first conductive film 54 by heat absorbed by the insulating film 38. In other words, the laser light L does not require complicated adjustments to keep from forming the hole 58 in the first conductive film 54. The hole 58 penetrates the first conductive film 54. However, the output and wavelength of the laser light L can be adjusted so as not to cut the first substrate 10. For example, if the laser light L has a wavelength of 1 μm or 0.5 μm, it passes through glass.

Also, as shown in FIG. 3, the first substrate 10 and the second substrate 12 are disposed to oppose the insulating film 38 and the second conductive film 40, interposed with the conductive material 60 touching an inner face of the hole 58 in the first conductive film 54 and the second conductive film 40.

It is possible to manufacture the display device pursuant to the embodiment of the present invention with a method that includes these processes. Also, the present invention is not to be construed to be limited to a device equipped with a mechanical shutter 14 as described above. It can be adopted for a liquid-crystal device or an organic electroluminescence display device.

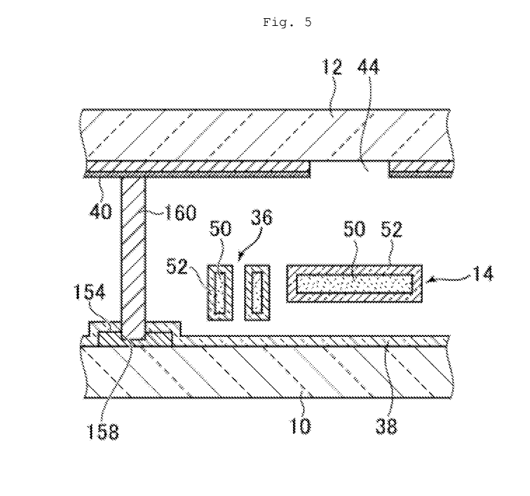

FIG. 5 is a view to explain a display device pursuant to an alternative embodiment of the present invention. In this example, the hole 158 in the first conductive film 154 is a concave portion that does not penetrate the first conductive film 154. Therefore, the conductive material 160 touches a bottom face of the concave portion.

The present invention is not limited to embodiment described above. A variety of alternatives is possible. Furthermore, it is possible to switch the features described in the embodiments above with features that are substantially the same, features that attain the same functional effects, or achieve the same object.

### EXPLANATION OF LETTERS OR NUMERALS

10 First substrate
12 Second substrate
14 Shutter
16 Drive opening
18 First spring
20 First anchor
22 First wiring
24 First unit
26 Second unit
28 Third unit
30 Second anchor
32 Second spring
34 Second wiring
36 Drive unit
38 Insulating film
40 Second conductive film
44 Fixed opening
46 Oil
48 Circuit layer
50 Core layer
52 Insulating film
54 First conductive film
56 Penetration hole
58 Hole
60 Conductive material
154 First conductive film
158 Hole
160 Conductive material

What is claimed is:

1. A method of manufacturing a display device comprising: providing a first substrate stacked with a circuit layer for displaying an image, the circuit layer covered by an insulation film, the circuit layer including a first conductive film;
forming a hole in the first conductive film by forming a penetration hole in the insulation film;
providing a second substrate with a second conductive film; and
disposing the first substrate and the second substrate such that the insulating film and the second conductive film are opposed, and interposing a conductive material to touch an inner face of the hole in the first conductive film and the second conductive film.

2. The method of manufacturing a display device according to claim 1, wherein
the hole is a penetration hole that penetrates the first conductive film.

3. The method of manufacturing a display device according to claim 1, wherein
the hole is a concave portion that does not penetrate the first conductive film; and
the conductive material is disposed to touch a bottom face of the concave portion.

4. The method of manufacturing a display device according to any one of claims 1-3, characterized in that
the first conductive film is a plurality of layers.

5. A display device comprising:
a first substrate stacked with a circuit layer for displaying an image; the circuit layer covered by an insulating film; the circuit layer including a first conductive film; a penetration hole formed in the insulating film; a hole formed in the first conductive film;
a second substrate formed with a second conductive film, arranged with the insulating film and the second conductive film opposed; and
conductive material interposed between the first substrate and the second substrate so that the conductive material touches an inner face of the hole in the first conductive film and the second conductive film.

6. The display device according to claim 5, wherein
the first substrate is equipped with a shutter to control the transmission and blocking of light; and a drive unit for driving the shutter; and
the shutter is covered by an insulating material composed of a same material as the insulating film.

7. The display device according to claim 6, wherein
the first conductive layer is electrically connected to the shutter.
